(19) United States
(12) Patent Application Publication
(10) Pub. No.: US 2019/0256532 A1
(43) Pub. Date: Aug. 22, 2019

(54) ALKYLAMINO-SUBSTITUTED CARBOSILANE PRECURSORS

(71) Applicants: American Air Liquide, Inc., Fremont, CA (US); L'Air Liquide, Société Anonyme pour I'Exploitation des Procédés GeorgesClaude, Paris (FR)

(72) Inventors: Claudia FAFARD, Newark, DE (US); Glenn KUCHENBEISER, Fremont, CA (US); Venkateswara R. PALLEM, Hockessin, DE (US); Jean-Marc GIRARD, Versailles (FR)

(21) Appl. No.: 16/398,679

(22) Filed: Apr. 30, 2019

Related U.S. Application Data
(62) Division of application No. 15/325,189, filed on Jan. 10, 2017.
(60) Provisional application No. 62/023,087, filed on Jul. 10, 2014.

(51) Int. Cl. C07F 7/10; C23C 16/455; C09D 1/00; C23C 16/24

(52) U.S. Cl. CPC C07F 7/10; C23C 16/24; C09D 1/00; C23C 16/45525

(57) ABSTRACT

Disclosed are Si-containing film forming compositions comprising alkylamino-substituted carbosilane precursors, methods of synthesizing the same, and their use for vapor deposition processes.

### CROSS REFERENCE TO RELATED APPLICATIONS

This application is a divisional of U.S. patent application Ser. No. 15/325,189, filed Jan. 10, 2017, which is a 371 of International PCT Application PCT/US2015/039681, filed Jul. 9, 2015, which claims the benefit of U.S. Provisional Application Ser. No. 62/023,087 filed Jul. 10, 2014, herein incorporated by reference in its entirety for all purposes.

### TECHNICAL FIELD

Disclosed are Si-containing film forming compositions comprising alkylamino-substituted carbosilane precursors, methods of synthesizing the same, and their use for vapor deposition processes.

### BACKGROUND

Si-containing thin films are used widely in the semiconductor, photovoltaic, LCD-TFT, flat panel-type device, refectory material, or aeronautic industries. Si-containing thin films may be used, for example, as dielectric materials having electrical properties which may be insulating (SiO₂, SiN, SiC, SiCN, SiCOH, MSiOₓ, wherein M is Hf, Zr, Ti, Nb, Ta, or Ge and x is greater than zero). Si-containing thin films may be used as conducting films, such as metal silicides or metal silicon nitrides. Due to the strict requirements imposed by downscaling of electrical device architectures towards the nanoscale (especially below 28 nm node), increasingly fine-tuned molecular precursors are required which meet the requirements of volatility (for vapor deposition processes), lower process temperatures, reactivity with various oxidants and low film contamination, in addition to high deposition rates, conformality, and consistency of films produced.

Fukazawa et al. (US2013/0224964) disclose a method of forming a dielectric film having Si—C bonds on a semiconductor substrate by atomic layer deposition (ALD). The precursor has a Si—C—Si bond in its molecule, and the reactant gas is oxygen-free and halogen-free and is constituted by at least a rare gas.

Vrtis et al. (EP2048700) disclose forming antireflective coatings using, amongst many others, R¹ₙ(OR²)ₚ(NR⁴_{z})₃₋ₙ₋ₚSi—R⁷—Si—R³ₘ(NR⁵_{z})_{q}(OR⁶)_{3-m-q}, wherein R¹ and R³ are independently H or C₁ to C₄ linear or branched, saturated, singly or multiply unsaturated, cyclic, partially or fully fluorinated hydrocarbon; R², R⁶, and R⁷ are independently C₁ to C₆ linear or branched, saturated, singly or multiply unsaturated, cyclic, aromatic, partially or fully fluorinated hydrocarbon, alternatively, R⁷ is an amine or an organoamine group; R⁴ and R⁵ are independently H, C₁ to C₆ linear or branched, saturated, singly or multiply unsaturated, cyclic, aromatic, partially or fully fluorinated hydrocarbon, z is 1 or 2; n is 0 to 3; m is 0 to 3; q is 0 to 3; and p is 0 to 3, provided that n+p≤3 and m+q≤3.

Ohhashi et al. (US2013/0206039) disclose monosilane or bisilane compounds having dimethylamino groups used in the hydrophobization treatment of surface substrates. The bisilane compounds have the formula R²_{b}[N(CH₃)₂]_{3-b}Si—R⁴—SiR³_{c}[N(CH₃)₂]_{3-c-}, wherein R² and R³ are each independently a hydrogen atom or a straight chain or branched chain alkyl group with 1 to 4 carbon atoms, R⁴ is a straight chain or branched chain alkylene group with 1 to 16 carbon atoms, and b and c are each independently an integer of 0 to 2.

Machida et al. (JP2002158223) disclose the formation of insulator films using Si-type materials with the formula: {R₃(R₄)N}₃Si—{C(R₁)R₂}ₙ—Si{N(R₅)R₆}₃, where R₁, R₂=H, hydrocarbon groups C1-3, or X(halogen atom)-substituted hydrocarbon groups (R₁ and R₂ can be same), n=1-5 integer, R₃, R₄, R₅ and R₆=H, hydrocarbon groups C1-3 or X(halogen atom)-substituted hydrocarbon groups (R₃, R₄, R₅ and R₆ can be same). The insulator films may be formed on substrates by CVD.

Jansen et al. (Z. Naturforsch. B. 52, 1997, 707-710) disclose the synthesis of bis[tris(methylamino)silyl]methane and bis[tris(phenylamino)silyl]methane as potential precursors of porous oxygen-free solids.

Despite the wide range of choices available for the deposition of Si-containing films, additional precursors are continuously sought to provide device engineers the ability to tune manufacturing process requirements and achieve films with desirable electrical and physical properties.

### Notation and Nomenclature

Certain abbreviations, symbols, and terms are used throughout the following description and claims, and include:

As used herein, the indefinite article “a” or “an” means one or more.

As used herein, the terms “approximately” or “about” mean ±10% of the value stated.

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used herein, the term “carbosilane” refers to a linear or branched molecule with a backbone having alternate Si and C atoms and at least one Si—C—Si unit.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, n-propyl groups, n-butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the term “aryl” refers to aromatic ring compounds where one hydrogen atom has been removed from the ring. As used herein, the term “heterocycle” refers to a cyclic compound that has atoms of at least two different elements as members of its ring.

As used herein, the abbreviation “Me” refers to a methyl group; the abbreviation “Et” refers to an ethyl group; the abbreviation “Pr” refers to any propyl group (i.e., n-propyl or isopropyl); the abbreviation “iPr” refers to an isopropyl group; the abbreviation “Bu” refers to any butyl group (n-butyl, iso-butyl, t-butyl, sec-butyl); the abbreviation “tBu” refers to a tert-butyl group; the abbreviation “sBu” refers to a sec-butyl group; the abbreviation “iBu” refers to an iso-butyl group; the abbreviation “Ph” refers to a phenyl group; the abbreviation “Am” refers to any amyl group (iso-amyl, sec-amyl, tert-amyl); the abbreviation “Cy” refers to a cyclic alkyl group (cyclobutyl, cyclopentyl, cyclohexyl, etc.); and the abbreviation “Ramd” refers to an R—N—C(Me)-N—R amidinate ligand, with R being an alkyl group (e.g., Pramd is iPr—N—C(Me)-N-iPr).

As used herein, the acronym “SRO” stands for a Strontium Ruthenium Oxide film; the acronym “HODS” stands for hexachlorodisilane; and the acronym “PODS” stands for pentachlorodisilane.

The standard abbreviations of the elements from the periodic table of elements are used herein. It should be understood that elements may be referred to by these abbreviations (e.g., Si refers to silicon, N refers to nitrogen, O refers to oxygen, C refers to carbon, etc.).

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is a ThermoGravimetric Analysis (TGA) graph demonstrating the percentage of weight loss with increasing temperature of [(EtHN)₃Si]₂CH₂, and

FIG. 2 is a TGA graph demonstrating the percentage of weight loss with increasing temperature of (iPrHN)H₂Si—CH₂—SiH₃.

### SUMMARY

Disclosed are Si-containing film forming compositions comprising alkylamino-substituted carbosilane precursors having the formula R₃Si—CH₂—SiR₃, wherein each R is independently H, an alkyl group, or an alkylamino group, provided that at least one R is an alkylamino group having the formula NR¹R², wherein R¹ and R² is each independently H, a C1-C6 alkyl group, a C1-C6 alkenyl group, or a C3-C10 aryl or heterocycle group, provided that, when every R is an alkylamino group, R¹≠R² when R¹ is Me or Et and R¹≠H when R² is Me or Ph. The disclosed precursors may include one or more of the following aspects:
At least one R being H;
Each R being selected from H or the alkylamino group;
R¹ and R² each independently being selected from H, Me, Et, nPr, iPr, Bu, or Am;
R¹ and R² each independently being selected from H, Me, Et, nPr, or iPr;
R¹ being H;
R¹ being Me;
R¹ being Et;
R¹ being nPr;
R¹ being iPr;
R¹ being Bu;
R¹ being Am;
R² being H;
R² being Me;
R² being Et;
R² being nPr;
R² being iPr;
R² being Bu;
R² being Am;
R¹ and R² being joined to form a cyclic chain on one N atom or on adjacent N atoms;
R¹ and R² forming pyridine, pyrole, pyrrolidine, or imidazole ring structures on one N atom;
R¹ and R² forming amidinate or diketimine ligands on adjacent N atoms;
the alkylamino-substituted carbosilane precursor having the formula:

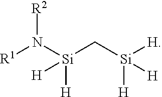

the alkylamino-substituted carbosilane precursor being (NMe₂)H₂Si—CH₂—SiH₃;
the alkylamino-substituted carbosilane precursor being (NEt₂)H₂Si—CH₂—SiH₃;
the alkylamino-substituted carbosilane precursor being (NMeEt)H₂Si—CH₂—SiH₃;
the alkylamino-substituted carbosilane precursor being (NEtH)H₂Si—CH₂—SiH₃;
the alkylamino-substituted carbosilane precursor being or (NiPrH)H₂Si—CH₂—SiH₃;
the alkylamino-substituted carbosilane precursor having the formula:

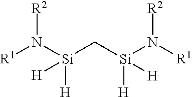

the alkylamino-substituted carbosilane precursor being (NMe₂) H₂Si—CH₂—SiH₂(NMe₂);
the alkylamino-substituted carbosilane precursor being (NEt₂)H₂Si—CH₂—SiH₂(NEt₂);
the alkylamino-substituted carbosilane precursor being (NMeEt)H₂Si—CH₂—SiH₂(NMeEt);
the alkylamino-substituted carbosilane precursor being (NEtH)H₂Si—CH₂—SiH₂(NEtH);
the alkylamino-substituted carbosilane precursor being (NiPrH)H₂Si—CH₂—SiH₂(NiPrH);
the alkylamino-substituted carbosilane precursor having the formula:

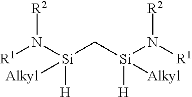

the alkylamino-substituted carbosilane precursor being (NMe₂) MeHSi—CH₂—SiHMe(NMe₂);
the alkylamino-substituted carbosilane precursor being (NEt₂)MeHSi—CH₂—SiHMe(NEt₂);
the alkylamino-substituted carbosilane precursor being (NMeEt)MeHSi—CH₂—SiHMe(NMeEt);
the alkylamino-substituted carbosilane precursor being (NEtH)MeHSi—CH₂—SiHMe(NEtH);
the alkylamino-substituted carbosilane precursor being (NiPrH)MeHSi—CH₂—SiHMe(NiPrH);
the alkylamino-substituted carbosilane precursor having the formula:

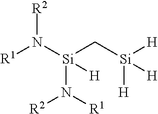

the alkylamino-substituted carbosilane precursor being (NMe₂)₂HSi—CH₂—SiH₃;
the alkylamino-substituted carbosilane precursor being (NEt₂)₂HSi—CH₂—SiH₃;
the alkylamino-substituted carbosilane precursor being (NMeEt)₂HSi—CH₂—SiH₃;
the alkylamino-substituted carbosilane precursor being (NEtH)₂HSi—CH₂—SiH₃;
the alkylamino-substituted carbosilane precursor being (NiPrH)₂HSi—CH₂—SiH₃;
the alkylamino-substituted carbosilane precursor having the formula:

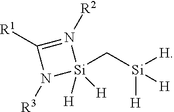

R³ being H, a C1 to C6 alkyl group, or a C3-C10 aryl or heterocycle group;
R³ being H, Me, Et, nPr, iPr, Bu, or Am;
R³ being H, Me, Et, nPr, or iPr;
R³ being H;
R³ being Me;
R³ being Et;
R³ being nPr;
R³ being iPr;
R³ being Bu;
R³ being Am;
the alkylamino-substituted carbosilane precursor being (^{me}amd)SiH₂—CH₂—SiH₃;
the alkylamino-substituted carbosilane precursor being (^{Et}amd)SiH₂—CH₂—SiH₃;
the alkylamino-substituted carbosilane precursor being (^{iPr}amd)SiH₂—CH₂—SiH₃;
the alkylamino-substituted carbosilane precursor being (^{tBu}amd)SiH₂—CH₂—SiH₃;
the alkylamino-substituted carbosilane precursor being (^{me}amd)SiH₂—CH₂—SiMe₃;
the alkylamino-substituted carbosilane precursor being (^{Et}amd)SiH₂—CH₂—SiMe₃;
the alkylamino-substituted carbosilane precursor being (^{iPr}amd)SiH₂—CH₂—SiMe₃;
the alkylamino-substituted carbosilane precursor being (^{tBu}amd)SiH₂—CH₂—SiMe₃;
the alkylamino-substituted carbosilane precursor having the formula:

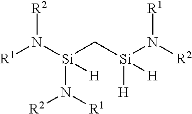

the alkylamino-substituted carbosilane precursor being (NMe₂)₂HSi—CH₂—SiH₂(NMe₂);
the alkylamino-substituted carbosilane precursor being (NEt₂)₂HSi—CH₂—SiH₂(NEt₂);
the alkylamino-substituted carbosilane precursor being (NMeEt)₂HSi—CH₂—SiH₂(NMeEt);
the alkylamino-substituted carbosilane precursor being (NEtH)₂HSi—CH₂—SiH₂(NEtH);
the alkylamino-substituted carbosilane precursor being (NiPrH)₂HSi—CH₂—SiH₂(NiPrH);
the alkylamino-substituted carbosilane precursor having the formula:

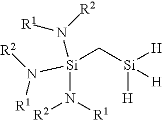

the alkylamino-substituted carbosilane precursor being (NMe₂)₃Si—CH₂—SiH₃;
the alkylamino-substituted carbosilane precursor being (NEt₂)₃Si—CH₂—SiH3;
the alkylamino-substituted carbosilane precursor being (NMeEt)₃Si—CH₂—SiH₃;
the alkylamino-substituted carbosilane precursor being (NEtH)₃Si—CH₂—SiH₃;
the alkylamino-substituted carbosilane precursor being (NiPrH)₃Si—CH₂—SiH₃;
the alkylamino-substituted carbosilane precursor having the formula:

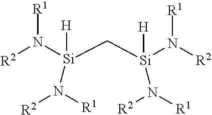

the alkylamino-substituted carbosilane precursor being (NMe₂)₂HSi—CH₂—SiH(NMe₂)₂;
the alkylamino-substituted carbosilane precursor being (NEt₂)₂HSi—CH₂—SiH(NEt₂)₂;
the alkylamino-substituted carbosilane precursor being (NMeEt)₂HSi—CH₂—SiH(NMeEt)₂;
the alkylamino-substituted carbosilane precursor being (NEtH)₂HSi—CH₂—SiH(NEtH)₂;
the alkylamino-substituted carbosilane precursor being (NiPrH)₂HSi—CH₂—SiH(NiPrH)₂;
the alkylamino-substituted carbosilane precursor having the formula:

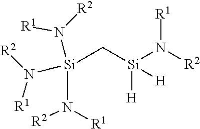

the alkylamino-substituted carbosilane precursor being (NMe₂)₃Si—CH₂—SiH₂(NMe₂);
the alkylamino-substituted carbosilane precursor being (NEt₂)₃Si—CH₂—SiH₂(NEt₂);
the alkylamino-substituted carbosilane precursor being (NMeEt)₃Si—CH₂—SiH₂(NMeEt);
the alkylamino-substituted carbosilane precursor being (NEtH)₃Si—CH₂—SiH₂(NEtH);
the alkylamino-substituted carbosilane precursor being (NiPrH)₃Si—CH₂—SiH₂(NiPrH);
the alkylamino-substituted carbosilane precursor having the formula:

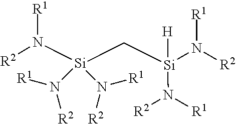

the alkylamino-substituted carbosilane precursor being (NMe₂)₃Si—CH₂—SiH(NMe₂)₂;
the alkylamino-substituted carbosilane precursor being (NEt₂)₃Si—CH₂—SiH(NEt₂)₂;
the alkylamino-substituted carbosilane precursor being (NMeEt)₃Si—CH₂—SiH(NMeEt)₂;
the alkylamino-substituted carbosilane precursor being (NEtH)₃Si—CH₂—SiH(NEtH)₂;
the alkylamino-substituted carbosilane precursor being (NiPrH)₃Si—CH₂—SiH(NiPrH)₂;
the alkylamino-substituted carbosilane precursor having the formula:

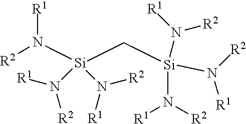

the alkylamino-substituted carbosilane precursor being (NMe₂)₃Si—CH₂—Si(NMe₂)₃;
the alkylamino-substituted carbosilane precursor being (NEt₂)₃Si—CH₂—Si(NEt₂)₃;
the alkylamino-substituted carbosilane precursor being (NMeEt)₃Si—CH₂—Si(NMeEt)₃;
the alkylamino-substituted carbosilane precursor being (NEtH)₃Si—CH₂—Si(NEtH)₃;
the alkylamino-substituted carbosilane precursor being (NiPrH)₃Si—CH₂—Si(NiPrH)₃;
the Si-containing film forming composition comprising between approximately 0.1 molar % and approximately 50 molar % of the carbosilane precursor;
the Si-containing film forming composition comprising between approximately 93% w/w to approximately 100% w/w of the carbosilane precursor;
the Si-containing film forming composition comprising between approximately 99% w/w to approximately 100% w/w of the carbosilane precursor;
the Si-containing film forming composition comprising between approximately 0% w/w and 5% w/w of hexane, substituted hexane, pentane, substituted pentane, dimethyl ether, or anisole;
the Si-containing film forming composition comprising between approximately 0 ppmw and 200 ppm of Cl;
further comprising a solvent;
the solvent being selected from the group consisting of C1-C16 hydrocarbons, THF, DMO, ether, pyridine, and combinations thereof;
the solvent being a C1-C16 hydrocarbons;
the solvent being tetrahydrofuran (THF);
the solvent being dimethyl oxalate (DMO);
the solvent being ether;
the solvent being pyridine;
the solvent being ethanol; or
the solvent being isopropanol.

Also disclosed are processes for the deposition of a Silicon-containing film on a substrate. The vapor of any of the Si-containing film forming compositions comprising the alkylamino-substituted carbosilane precursors disclosed above is introduced into a reactor having a substrate disposed therein. At least part of the alkylamino-substituted carbosilane precursor is deposited onto the substrate to form the Silicon-containing film. The disclosed processes include one or more of the following aspects:
introducing a reactant into the reactor;
the reactant being plasma-treated;
the reactant being remote plasma-treated;
the reactant not being plasma-treated;
the reactant being selected from the group consisting of H₂, H₂CO N₂H₄, NH₃, SiH₄, Si₂H₆, Si₃H₈, SiH₂Me₂, SiH₂Et₂, N(SiH₃)₃, hydrogen radicals thereof, and mixtures thereof;
the reactant being H₂;
the reactant being NH₃,
the reactant being selected from the group consisting of: O₂, O₃, H₂O, H₂O₂ NO, N₂O, NO₂, oxygen radicals thereof, and mixtures thereof;
the reactant being H₂O;
the reactant being plasma treated O₂;
the reactant being O₃;
the Si-containing film forming composition and the reactant being introduced into the reactor simultaneously;
the reactor being configured for chemical vapor deposition;
the Si-containing film forming composition and the reactant being introduced into the chamber sequentially;
the reactor being configured for atomic layer deposition;
the deposition being plasma enhanced.

### DETAILED DESCRIPTION OF PREFERRED EMBODIMENTS

Disclosed are Si-containing film forming compositions comprising alkylamino-substituted carbosilane precursors, methods of synthesizing the same, and methods of using the same to deposit silicon-containing films for manufacturing semiconductors.

The disclosed alkylamino-substituted carbosilane precursors have the formula R₃Si—CH₂—SiR₃, wherein each R is independently H, an alkyl group, or an alkylamino group, provided that at least one R is an alkylamino group having the formulaNR¹R², wherein each R′ is independently H, a C1-C6 alkyl group, a C1-C6 alkenyl group, or a C3-C10 aryl or heterocycle group, provided that, when every R is an alkylamino group, R¹≠R² when R¹ is Me or Et and R¹≠H when R² is Me or Ph. Preferably, R¹ and R² is each independently H, Me, Et, nPr, iPr, Bu, or Am. R¹ and R² may be joined to form a cyclic chain on one N atom or on adjacent N atoms. For example, R¹ and R² may form pyridine, pyrole, pyrrolidine, or imidazole ring structures on one N atom or amidinate or diketimine ligands on adjacent N atoms.

Preferably at least one R is H because the hydrogen bonded to the Si atom may help increase the volatility of the precursor. Additionally, in ALD processes, the Si—H bonds of the disclosed precursors may help to provide a larger growth rate per cycle when compared to the analogous carbosilane precursors because the H atoms occupy less surface area, resulting in more molecules on the substrate surface.

Preferably, at least R¹ or R² is H because the hydrogen bonded to the N atom may help increase the volatility of the precursor. Additionally, in ALD processes, the N—H bonds of the disclosed precursors may help to provide a larger growth rate per cycle when compared to the analogous carbosilane precursors because the H atoms occupy less surface area, resulting in more molecules on the substrate surface. NH also provides improved reactivity when compared to NR molecules.

Even more preferably, at least one R is H and R¹ or R² is H for the same reasons described above.

One of ordinary skill in the art will recognize that at least one R may include an alkyl group, such as Me, Et, Pr, or Bu, when deposited films having some carbon are desired.

Exemplary alkylamino-substituted carbosilane precursors having one alkylamino group include:

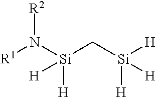

wherein R¹ and R² is each independently H, a C1-C6 alkyl group, a C1-C6 alkenyl group, or a C3-C10 aryl or heterocycle group. Preferably, R₁ and R₂ is each independently H, Me, Et, nPr, iPr, Bu, or Am. R₁ and R₂ may be joined to form a cyclic chain on the N atom. For example, NR₁R₂ may form pyridine, pyrole, pyrrolidine, or imidazole ring structures.

Exemplary mono-alkylamino substituted precursors include (NMe₂)H₂Si—CH₂—SiH₃, (NEt₂)H₂Si—CH₂—SiH₃, (NMeEt)H₂Si—CH₂—SiH₃, (NEtH)H₂Si—CH₂—SiH₃, or (NiPrH)H₂Si—CH₂—SiH₃.

The monoalkylamino-1,3-disilapropane may be synthesized at low temperatures (−78° C. to 0° C.) by mixing or dissolving excess amine and a nonpolar solvent. 1-chloro-1,3-disilapropane is slowly added to the mixture to form the desired compound. The reactants are commercially available or may be synthesized according to J. Organomet. Chem. 92, 1975 163-168.

Alternatively, alkyl lithium is combined with a primary or secondary amine (NH₂R or NHR₂) in a solvent, such as ether or any other polar solvents, at low temperatures (approximately −78° C. to 0° C.) to form lithium amide. The lithium amide may be isolated and reacted with 1-chloro-1,3-disilapropane to form the desired compound. Alternatively, the lithium amide solution may be added to 1-chloro-1,3-disilapropane to form the desired compound.

Exemplary alkylamino-substituted carbosilane precursors having two alkylamino groups include symmetric molecules having the formula:

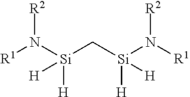

or asymmetric molecules having the fomula:

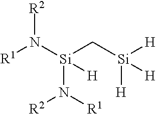

wherein R¹ and R² is each independently H, a C1-C6 alkyl group, a C1-C6 alkenyl group, or a C3-C10 aryl or heterocycle group. Preferably, R₁ and R₂ is each independently H, Me, Et, nPr, iPr, Bu, or Am. R₁ and R₂ may be joined to form a cyclic chain on one N atom or, on the unsymmetric compound, on adjacent N atoms. For example, NR₁R₂ may form pyridine, pyrole, pyrrolidine, or imidazole ring structures or, on the unsymmetric compound, R₁—N—Si—N—R₂ may form an amidinate or diketiminate structure.

Exemplary asymmetric di-alkylamino substituted precursors include (NMe₂)₂HSi—CH₂—SiH₃, (NEt₂)₂HSi—CH₂—SiH₃, (NMeEt)₂HSi—CH₂—SiH₃, (NEtH)₂HSi—CH₂—SiH₃, or (NiPrH)₂HSi—CH₂—SiH₃.

Exemplary symmetric di-alkylamino substituted precursors include (NMe₂) H₂Si—CH₂—SiH₂(NMe₂), (NEt₂)H₂Si—CH₂—SiH₂(NEt₂), (NMeEt)H₂Si—CH₂—SiH₂(NMeEt), (NEtH)H₂Si—CH₂—SiH₂(NEtH), or (NiPrH)H₂Si—CH₂—SiH₂(NiPrH).

At low temperatures (−78° C. to 0° C.), excess amine is mixed with or dissolved in a nonpolar solvent. 1,1-dichloro-1,3-disilapropane or 1,3-dichloro-1,3-disilapropane is slowly added to form the desired compound. The reactants are commercially available or may be synthesized according to J. Organomet. Chem. 92, 1975 163-168.

Alternatively, at low temperatures (approximately −78° C. to 0° C.), alkyl lithium is combined with a primary or secondary amine (NH₂R or NHR₂) in a solvent, such as ether or any other polar solvents, to form lithium amide. The lithium amide may be isolated and reacted with 1,1-dichloro-1,3-disilapropane or 1,3-dichloro-1,3-disilapropane to form the desired compound. Alternatively, the lithium amide solution may be added to 1,1-dichloro-1,3-disilapropane or 1,3-dichloro-1,3-disilapropane to form the desired compound.

Exemplary alkylamino-substituted carbosilane precursors having 2 alkylamino groups with the adjacent N atoms joined by an unsaturated alkyl chain to form an amidinate ligand include:

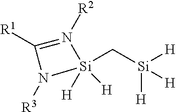

wherein R¹, R², R³ may each independently be H, a C1 to C6 alkyl group, or a C3-C10 aryl or heterocycle group. R¹ and R² and/or R¹ and R³ may also be joined to form cyclic chains.

Exemplary amidinate substituted carbosilane precursors include (^{Me}amd)SiH₂—CH₂—Si H₃, (^{Et}amd)SiH₂—CH₂—SiH₃, (^{iPr}amd)SiH₂—CH₂—SiH₃, (^{tBu}amd)SiH₂—CH₂—SiH₃, (^{Me}amd)SiH₂—CH₂—SiMe₃, (^{Et}amd)SiH₂—CH₂—SiMe₃, (^{iPr}amd)SiH₂—CH₂—SiMe₃, or (^{tBu}amd)SiH₂—CH₂—SiMe₃.

At lower temperatures (approximately 0° C. to approximately room temperature (25°)), alkyl lithium is combined with carbodiimide in a solvent, such as ether or any other polar solvents, to form lithium amidinate. The reaction is exothermic. The lithium amidinate may be isolated and reacted with 1-chloro-1,3-disilapropane to form the desired compound. Alternatively, the lithium amidinate solution may be added to 1-chloro-1,3-disilapropane to form the desired compound.

Exemplary alkylamino-substituted carbosilane precursors having two alkylamino groups include molecules having the following formula:

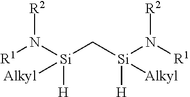

wherein R¹ and R² is each independently H, a C1-C6 alkyl group, a C1-C6 alkenyl group, or a C3-C10 aryl or heterocycle group. Preferably, R₁ and R₂ is each independently H, Me, Et, nPr, iPr, Bu, or Am. R₁ and R₂ may be joined to form a cyclic chain on one N atom or, on the unsymmetric compound, on adjacent N atoms. For example, NR₁R₂ may form pyridine, pyrole, pyrrolidine, or imidazole ring structures the alkylamino-substituted carbosilane precursor or, on the unsymmetric compound, R₁—N—Si—N—R₂ may form an amidinate or diketiminate structure.

Exemplary asymmetric di-alkylamino substituted precursors include (NMe₂) MeHSi—CH₂—SiHMe(NMe₂), (NEt₂)MeHSi—CH₂—SiHMe(NEt₂), (NMeEt)MeHSi—CH₂—SiHMe(NMeEt), (NEtH)MeHSi—CH₂—SiHMe(NEtH), or (NiPrH)MeHSi—CH₂—SiHMe(NiPrH).

Exemplary alkylamino-substituted carbosilane precursors having 3 alkylamino groups are all asymmetric and include:

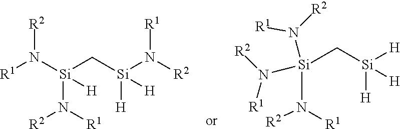

wherein R¹ and R² is each independently H, a C1-C6 alkyl group, a C1-C6 alkenyl group, or a C3-C10 aryl or heterocycle group. Preferably, R₁ and R₂ is each independently H, Me, Et, nPr, iPr, Bu, or Am. R₁ and R₂ may be joined to form a cyclic chain on one N atom or on adjacent N atoms. For example, NR₁R₂ may form pyridine, pyrole, pyrrolidine, or imidazole ring structures or R₁—N—Si—N—R₂ may form an amidinate or diketiminate structure.

Exemplary tri-alkylamino substituted precursors include (NMe₂)₃Si—CH₂—SiH₃, (NEt₂)₃Si—CH₂—SiH₃, (NMeEt)₃Si—CH₂—SiH₃, (NEtH)₃Si—CH₂—SiH₃, or (NiPrH)₃Si—CH₂—SiH₃.

Alternatively, the exemplary tri-alkylamino substituted precursors include (NMe₂)₂HSi—CH₂—SiH₂(NMe₂), (NEt₂)₂HSi—CH₂—SiH₂(NEt₂), (NMeEt)₂HSi—CH₂—SiH₂(NMeEt), (NEtH)₂HSi—CH₂—SiH₂(NEtH), or (NiPrH)₂HSi—CH₂—SiH₂(NiPrH).

At low temperatures (−78° C. to 0° C.), excess amine is mixed with or dissolved in a nonpolar solvent. 1,1,1-trichloro-1,3-disilapropane or 1,1,3-trichloro-1,3-disilapropane is slowly added to form the desired compound. The reactants are commercially available or may be synthesized according to J. Organomet. Chem. 92, 1975 163-168.

Alternatively, at low temperatures (approximately −78° C. to 0° C.), alkyl lithium is combined with a primary or secondary amine (NH₂R or NHR₂) in a solvent, such as ether or any other polar solvents, to form lithium amide. The lithium amide may be isolated and reacted with 1,1,1-trichloro-1,3-disilapropane or 1,1,3-trichloro-1,3-disilapropane to form the desired compound. Alternatively, the lithium amide solution may be added to 1,1,1-trichloro-1,3-disilapropane or 1,1,3-trichloro-1,3-disilapropane to form the desired compound.

Exemplary alkylamino-substituted carbosilane precursors having 4 alkylamino groups include symmetric molecules having the formula:

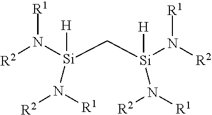

or asymmetric molecules having the formula:

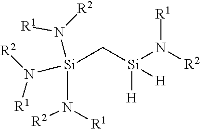

wherein R¹ and R² is each independently H, a C1-C6 alkyl group, a C1-C6 alkenyl group, or a C3-C10 aryl or heterocycle group. Preferably, R₁ and R₂ is each independently H, Me, Et, nPr, iPr, Bu, or Am. R₁ and R₂ may be joined to form a cyclic chain on one N atom or on adjacent N atoms. For example, NR₁R₂ may form pyridine, pyrole, pyrrolidine, or imidazole ring structures or R₁—N—Si—N—R₂ may form an amidinate or diketiminate structure.

Exemplary assymetrical tetra-alkylamino substituted precursors include (NMe₂)₃Si—CH₂—SiH₂(NMe₂), (NEt₂)₃Si—CH₂—SiH₂(NEt₂), (NMeEt)₃Si—CH₂—SiH₂(NMeEt), (NEtH)₃Si—CH₂—SiH₂(NEtH), or (NiPrH)₃Si—CH₂—SiH₂(NiPrH).

Exemplary symetrical tetra-alkylamino substituted precursors include (NMe₂)₂HSi—CH₂—SiH(NMe₂)₂, (NEt₂)₂HSi—CH₂—SiH(NEt₂)₂, (NMeEt)₂HSi—CH₂—SiH(NMeEt)₂, (NEtH)₂HSi—CH₂—SiH(NEtH)₂, or (NiPrH)₂HSi—CH₂—SiH(NiPrH)₂.

At low temperatures (−78° C. to 0° C.), excess amine is mixed with or dissolved in a nonpolar solvent. 1,1,1,3-tetrachloro-1,3-disilapropane or 1,1,3,3-tetrachloro-1,3-disilapropane is slowly added to form the desired compound. The reactants are commercially available or may be synthesized according to J. Organomet. Chem. 92, 1975 163-168.

Alternatively, at low temperatures (approximately −78° C. to 0° C.), alkyl lithium is combined with a primary or secondary amine (NH₂R or NHR₂) in a solvent, such as ether or any other polar solvents, to form lithium amide. The lithium amide may be isolated and reacted with 1,1,1,3-tetrachloro-1,3-disilapropane or 1,1,3,3-tetrachloro-1,3-disilapropane to form the desired compound. Alternatively, the lithium amide solution may be added to 1,1,1,3-tetrachloro-1,3-disilapropane or 1,1,3,3-tetrachloro-1,3-disilapropane to form the desired compound.

Exemplary alkylamino-substituted carbosilane precursors having 5 alkylamino groups are all asymmetric and include:

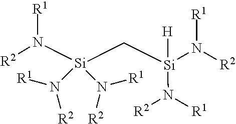

wherein R¹ and R² is each independently H, a C1-C6 alkyl group, a C1-C6 alkenyl group, or a C3-C10 aryl or heterocycle group. Preferably, R₁ and R₂ is each independently H, Me, Et, nPr, iPr, Bu, or Am. R₁ and R₂ may be joined to form a cyclic chain on one N atom or on adjacent N atoms. For example, NR₁R₂ may form pyridine, pyrole, pyrrolidine, or imidazole ring structures or R₁—N—Si—N—R₂ may form an amidinate or diketiminate structure.

Exemplary penta-alkylamino substituted precursors include (NMe₂)₃Si—CH₂—SiH(NMe₂)₂, (NEt₂)₃Si—CH₂—SiH(NEt₂)₂, (NMeEt)₃Si—CH₂-SiH(NMeEt)₂, (NEtH)₃Si—CH₂—SiH(NEtH)₂, or (NiPrH)₃Si—CH₂—SiH(NiPrH)₂.

At low temperatures (−78° C. to 0° C.), excess amine is mixed with or dissolved in a nonpolar solvent. 1,1,1,3,3-pentachloro-1,3-disilapropane is slowly added to form the desired compound. The reactants are commercially available or may be synthesized according to J. Organomet. Chem. 92, 1975 163-168.

Alternatively, at low temperatures (approximately −78° C. to 0° C.), alkyl lithium is combined with a primary or secondary amine (NH₂R or NHR₂) in a solvent, such as ether or any other polar solvents, to form lithium amide. The lithium amide may be isolated and reacted with 1,1,1,3,3-pentachloro-1,3-disilapropane to form the desired compound. Alternatively, the lithium amide solution may be added to 1,1,1,3,3-pentachloro-1,3-disilapropane to form the desired compound.

Exemplary alkylamino-substituted carbosilane precursors having 6 alkylamino groups include:

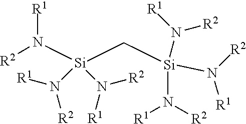

wherein R¹ and R² is each independently H, a C1-C6 alkyl group, a C1-C6 alkenyl group, or a C3-C10 aryl or heterocycle group, provided that R¹≠R² when R¹ is Me or Et and R¹≠H when R² is Me or Ph. Preferably, R₁ and R₂ is each independently H, Me, Et, nPr, iPr, Bu, or Am. R₁ and R₂ may be joined to form a cyclic chain on one N atom or on adjacent N atoms. For example, NR₁R₂ may form pyridine, pyrole, pyrrolidine, or imidazole ring structures or R₁—N—Si—N—R₂ may form an amidinate or diketiminate structure.

Exemplary hexa-alkylamino substituted precursors include (NMe₂)₃Si—CH₂—Si(NMe₂)₃, (NEt₂)₃Si—CH₂—Si(NEt₂)₃, (NMeEt)₃Si—CH₂-Si(NMeEt)₃, (NEtH)₃Si—CH₂—Si(NEtH)₃, or (NiPrH)₃Si—CH₂—Si(NiPrH)₃.

At low temperatures (−78° C. to 0° C.), excess amine is mixed with or dissolved in a nonpolar solvent. 1,1,1,3,3,3-hexachloro-1,3-disilapropane [or bis(trichlorosilyl)methane] is slowly added to form the desired compound. The reactants are commercially available.

Alternatively, at low temperatures (approximately −78° C. to 0° C.), alkyl lithium is combined with a primary or secondary amine (NH₂R or NHR₂) in a solvent, such as ether or any other polar solvents, to form lithium amide. The lithium amide may be isolated and reacted with bis(trichlorosilyl)methane to form the desired compound. Alternatively, the lithium amide solution may be added to bis(trichlorosilyl)methane to form the desired compound.

For all of the synthesis processes, one of ordinary skill in the art will recognize that Si—C bonds are not affected by the reactants used for amination of the silicon, and that the addition of alkyl groups on the Si atoms in a molecule having a disilapropane backbone may be achieved by selecting the starting disilapropane halide having the selected alkyl ligands on the silicon. For instance, the synthesis of Me(NMe₂)ClSi—CH₂—SiCI(NMe₂) Me would proceed under similar conditions as the synthesis of (NMe₂)₂CISi—CH₂—SiCl(NMe₂)₂, using 1,1,3,3-tetrachloro-1,3-dimethyldisilapropane in place of 1,1,1,3,3,3-hexachlorodisilapropane and half the amount of amine.

To ensure process reliability, the silicon-containing film forming compositions may be purified by continuous or fractional batch distillation or sublimation prior to use to a purity ranging from approximately 93% w/w to approximately 100% w/w, preferably ranging from approximately 99% w/w to approximately 100% w/w. The silicon-containing film forming compositions may contain any of the following impurities: undesired congeneric species; solvents; chlorinated metal compounds; or other reaction products. In one alternative, the total quantity of these impurities is below 0.1% w/w.

The concentration of each of hexane, substituted hexane, pentane, substituted pentane, dimethyl ether, or anisole in the purified silicon-containing film forming composition may range from approximately 0% w/w to approximately 5% w/w, preferably from approximately 0% w/w to approximately 0.1% w/w. Solvents may be used in the composition's synthesis. Separation of the solvents from the precursor may be difficult if both have similar boiling points. Cooling the mixture may produce solid precursor in liquid solvent, which may be separated by filtration. Vacuum distillation may also be used, provided the precursor product is not heated above approximately its decomposition point.

In one alternative, the disclosed Si-containing film forming compositions contain less than 5% v/v, preferably less than 1% v/v, more preferably less than 0.1% v/v, and even more preferably less than 0.01% v/v of any of its undesired congeneric species, reactants, or other reaction products. This alternative may provide better process repeatability. This alternative may be produced by distillation of the Si-containing film forming compositions.

In another alternative, the disclosed Si-containing film forming compositions may contain between 5% v/v and 50% v/v of one or more of its congeneric species, reactants, or other reaction products, particularly when the mixture provides improved process parameters or isolation of the target compound is too difficult or expensive. For example, a mixture of reaction products may produce a stable, liquid mixture suitable for spin-on or vapor deposition.

The concentration of trace metals and metalloids in the purified silicon-containing film forming compositions may each range from approximately 0 ppb to approximately 100 ppb, and more preferably from approximately 0 ppb to approximately 10 ppb. The concentration of X (wherein X=CI, Br, I, or F) in the purified silicon-containing film forming compositions may range from approximately 0 ppm to approximately 100 ppm and more preferably from approximately 0 ppm to approximately 10 ppm.

The disclosed alkylamino-substituted carbosilane precursors in the Si-containing film forming compositions may prove useful as monomers for the synthesis of carbosilane containing polymers. The Si-containing film forming compositions may be used to form spin-on dielectric film formulations, for patternable films, or for anti-reflective films. For example, the disclosed Si-containing film forming compostions may be included in a solvent and applied to a substrate to form a film. If necessary, the substrate may be rotated to evenly distribute the Si-containing film forming composition across the substrate. One of ordinary skill in the art will recognize that the viscosity of the Si-containing film forming compositions will contribute as to whether rotation of the substrate is necessary. The resulting film may be heated under an inert gas, such as Argon, Helium, or nitrogen and/or under reduced pressure. Alternatively, electron beams or ultraviolet radiation may be applied to the resulting film. The 6 hydrolysable groups of the disclosed alkylamino-substituted carbosilane precursors (i.e. no direct Si—C bonds except the bonds to the central carbo atoms) may prove useful to increase the connectivity of the polymer obtained.

The Si-containing film forming compositions may also be used for vapor deposition methods. The disclosed methods provide for the use of the Si-containing film forming compositions for deposition of silicon-containing films. The disclosed methods may be useful in the manufacture of semiconductor, photovoltaic, LCD-TFT, or flat panel type devices. The method includes: introducing the vapor of the disclosed Si-containing film forming compositions into a reactor having at least one substrate disposed therein: and using a vapor deposition process to deposit at least part of the disclosed alkylamino-substituted carbosilane precursor onto the substrate to form a Si-containing layer.

The disclosed methods also provide for forming a bimetal-containing layer on a substrate using a vapor deposition process and, more particularly, for deposition of SiMOₓ films, wherein x may be 0-4 and M is Ta, Hf, Nb, Mg, Al, Sr, Y, Ba, Ca, As, Sb, Bi, Sn, Pb, Co, lanthanides (such as Er), or combinations thereof.

The disclosed methods of forming silicon-containing layers on substrates may be useful in the manufacture of semiconductor, photovoltaic, LCD-TFT, or flat panel type devices. The disclosed Si-containing film forming compositions may deposit Si-containing films using any vapor deposition methods known in the art. Examples of suitable vapor deposition methods include chemical vapor deposition (CVD) or atomic layer deposition (ALD). Exemplary CVD methods include thermal CVD, plasma enhanced CVD (PECVD), pulsed CVD (PCVD), low pressure CVD (LPCVD), sub-atmospheric CVD (SACVD) or atmospheric pressure CVD (APCVD), hot-wire CVD (HWCVD, also known as cat-CVD, in which a hot wire serves as an energy source for the deposition process), radicals incorporated CVD, and combinations thereof. Exemplary ALD methods include thermal ALD, plasma enhanced ALD (PEALD), spatial isolation ALD, hot-wire ALD (HWALD), radicals incorporated ALD, and combinations thereof. Super critical fluid deposition may also be used. The disclosed methods may also be used in the flowable PECVD deposition processes described in U.S. Pat. App. Pub. No. 2014/0051264 to Applied Materials, Inc., the contents of which is incorporated herein in its entirety. The deposition method is preferably ALD, spatial ALD, or PE-ALD.

The vapor of the Si-containing film forming composition is introduced into a reaction chamber containing at least one substrate. The temperature and the pressure within the reaction chamber and the temperature of the substrate are held at conditions suitable for vapor deposition of at least part of the alkylamino-substituted carbosilane precursor onto the substrate. In other words, after introduction of the vaporized Si-containing film forming composition into the chamber, conditions within the chamber are such that at least part of the alkylamino-substituted carbosilane precursor is deposited onto the substrate to form the silicon-containing film. A co-reactant may also be used to help in formation of the Si-containing layer.

The reaction chamber may be any enclosure or chamber of a device in which deposition methods take place, such as, without limitation, a parallel-plate type reactor, a cold-wall type reactor, a hot-wall type reactor, a single-wafer reactor, a multi-wafer reactor, or other such types of deposition systems. All of these exemplary reaction chambers are capable of serving as an ALD reaction chamber. The reaction chamber may be maintained at a pressure ranging from about 0.5 mTorr to about 20 Torr. In addition, the temperature within the reaction chamber may range from about 20° C. to about 600° C. One of ordinary skill in the art will recognize that the temperature may be optimized through mere experimentation to achieve the desired result.

The temperature of the reactor may be controlled by controlling the temperature of the substrate holder and/or controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 20° C. to approximately 600° C. When a plasma deposition process is utilized, the deposition temperature may range from approximately 20° C. to approximately 550° C. Alternatively, when a thermal process is performed, the deposition temperature may range from approximately 300° C. to approximately 600° C.

Alternatively, the substrate may be heated to a sufficient temperature to obtain the desired silicon-containing film at a sufficient growth rate and with desired physical state and composition. A non-limiting exemplary temperature range to which the substrate may be heated includes from 150° C. to 600° C. Preferably, the temperature of the substrate remains less than or equal to 500° C.

The type of substrate upon which the silicon-containing film will be deposited will vary depending on the final use intended. A substrate is generally defined as the material on which a process is conducted. The substrates may be any suitable substrate used in semiconductor, photovoltaic, flat panel, or LCD-TFT device manufacturing. Examples of suitable substrates include wafers, such as silicon, silica, glass, plastic, Ge, or GaAs wafers. The wafer may have one or more layers of differing materials deposited on it from a previous manufacturing step. For example, the wafers may include silicon layers (crystalline, amorphous, porous, etc.), silicon oxide layers, silicon nitride layers, silicon oxy nitride layers, carbon doped silicon oxide (SiCOH) layers, or combinations thereof. Additionally, the wafers may include copper layers, tungsten layers or metal layers (e.g. platinum, palladium, nickel, rhodium, or gold). The wafers may include barrier layers, such as manganese, manganese oxide, tantalum, tantalum nitride, etc. Plastic layers, such as poly(3,4-ethylenedioxythiophene)poly (styrenesulfonate) [PEDOT:PSS] may also be used. The layers may be planar or patterned. In some embodiments, the substrate may be a patterened photoresist film made of hydrogenated carbon, for example CHₓ, wherein x is greater than zero (e.g., x≤4). In some embodiments, the substrate may include layers of oxides which are used as dielectric materials in MIM, DRAM, or FeRam technologies (for example, ZrO₂ based materials, HfO₂ based materials, TiO₂ based materials, rare earth oxide based materials, ternary oxide based materials, etc.) or from nitride-based films (for example, TaN) that are used as an oxygen barrier between copper and the low-k layer. The disclosed processes may deposit the silicon-containing layer directly on the wafer or directly on one or more than one (when patterned layers form the substrate) of the layers on top of the wafer. Furthermore, one of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates. The actual substrate utilized may also depend upon the specific precursor embodiment utilized. In many instances though, the preferred substrate utilized will be selected from hydrogenated carbon, TiN, SRO, Ru, and Si type substrates, such as polysilicon or crystalline silicon substrates.

The disclosed Si-containing film forming compositions may be supplied either in neat form or in a blend with a suitable solvent, such as toluene, ethyl benzene, xylene, mesitylene, decane, dodecane, octane, hexane, pentane, tertiary amines, acetone, tetrahydrofuran, ethanol, ethylmethylketone, 1,4-dioxane, or others. The disclosed Si-containing film forming compositions may be present in varying concentrations in the solvent. For example, the resulting concentration may range from approximately 0.05 M to approximately 2 M.

The neat or blended Si-containing film forming compositions are introduced into a reactor in vapor form by conventional means, such as tubing and/or flow meters. The composition in vapor form may be produced by vaporizing the neat or blended composition through a conventional vaporization step such as direct vaporization, distillation, by bubbling, or by using a sublimator such as the one disclosed in PCT Publication WO2009/087609 to Xu et al. The neat or blended composition may be fed in liquid state to a vaporizer where it is vaporized before it is introduced into the reactor. Alternatively, the neat or blended composition may be vaporized by passing a carrier gas into a container containing the composition or by bubbling the carrier gas into the composition. The carrier gas may include, but is not limited to, Ar, He, or N₂, and mixtures thereof. Bubbling with a carrier gas may also remove any dissolved oxygen present in the neat or blended composition. The carrier gas and composition are then introduced into the reactor as a vapor.

If necessary, the container may be heated to a temperature that permits the Si-containing film forming composition to be in its liquid phase and to have a sufficient vapor pressure. The container may be maintained at temperatures in the range of, for example, 0-150° C. Those skilled in the art recognize that the temperature of the container may be adjusted in a known manner to control the amount of Si-containing film forming composition vaporized.

In addition to the disclosed Si-containing film forming composition, a reaction gas may also be introduced into the reactor. The reaction gas may be an oxidizing agent such as one of O₂; O₃; H₂O; H₂O₂; oxygen containing radicals such as O− or OH−; NO; NO₂; carboxylic acids such as formic acid, acetic acid, propionic acid; radical species of NO, NO₂, or the carboxylic acids; para-formaldehyde; and mixtures thereof. Preferably, the oxidizing agent is selected from the group consisting of O₂, O₃, H₂O, H₂O₂, oxygen containing radicals thereof such as O− or OH−, and mixtures thereof. Preferably, when an ALD process is performed, the co-reactant is plasma treated oxygen, ozone, or combinations thereof. When an oxidizing gas is used, the resulting silicon containing film will also contain oxygen.

Alternatively, the reaction gas may be a reducing agent such as one of H₂, NH₃, (SiH₃)₃N, hydridosilanes (such as SiH₄, Si₂H₆, Si₃H₈, Si₄H₁₀, Si₅H₁₀, Si₆H₁₂), chlorosilanes and chloropolysilanes (such as SiHCl₃, SiH₂Cl₂, SiH₃Cl, Si₂Cl₆, Si₂HCl₅, Si₃Cl₈), alkylsilanes (such as (CH₃)₂SiH₂, (C₂H₅)₂SiH₂, (CH₃)SiH₃, (C₂H₅)SiH₃), hydrazines (such as N₂H₄, MeHNNH₂, MeHNNHMe), organic amines (such as N(CH₃)H₂, N(C₂H₅)H₂, N(CH₃)₂H, N(C₂H₅)₂H, N(CH₃)₃, N(C₂H₅)₃, (SiMe₃)₂NH), pyrazoline, pyridine, B-containing molecules (such as B₂H₆, 9-borabicyclo[3,3,1]none, trimethylboron, triethylboron, borazine), alkyl metals (such as trimethylaluminum, triethylaluminum, dimethylzinc, diethylzinc), radical species thereof, and mixtures thereof. Preferably, the reducing agent is H₂, NH₃, SiH₄, Si₂H₆, Si₃H₈, SiH₂Me₂, SiH₂Et₂, N(SiH₃)₃, hydrogen radicals thereof, or mixtures thereof. When a reducing agent is used, the resulting silicon containing film may be pure Si.

The reaction gas may be treated by a plasma, in order to decompose the reaction gas into its radical form. N₂ may also be utilized as a reducing agent when treated with plasma. For instance, the plasma may be generated with a power ranging from about 50 W to about 500 W, preferably from about 100 W to about 200 W. The plasma may be generated or present within the reactor itself. Alternatively, the plasma may generally be at a location removed from the reactor, for instance, in a remotely located plasma system. One of skill in the art will recognize methods and apparatus suitable for such plasma treatment.

When the desired silicon-containing film also contains another element, such as, for example and without limitation, Ta, Hf, Nb, Mg, Al, Sr, Y, Ba, Ca, As, Sb, Bi, Sn, Pb, Co, lanthanides (such as Er), or combinations thereof, the co-reactants may include a metal-containing precursor which is selected from, but not limited to, metal alkyls, such as Ln(RCp)₃ or Co(RCp)₂, metal amines, such as Nb(Cp)(NtBu)(NMe₂)₃ and any combination thereof.

The disclosed Si-containing film forming compositions may also be used with a halosilane or polyhalodisilane, such as hexachlorodisilane, pentachlorodisilane, or tetrachlorodisilane, or octachlorotrisilane and one or more co-reactant gases to form SiN or SiCN films, as disclosed in PCT Publication Number WO2011/123792, the entire contents of which are incorporated herein in their entireties.

The Si-containing film forming compositions and one or more co-reactants may be introduced into the reaction chamber simultaneously (chemical vapor deposition), sequentially (atomic layer deposition), or in other combinations. For example, the Si-containing film forming composition may be introduced in one pulse and two additional metal sources may be introduced together in a separate pulse [modified atomic layer deposition]. Alternatively, the reaction chamber may already contain the co-reactant prior to introduction of the Si-containing film forming composition. The co-reactant may be passed through a plasma system localized or remotely from the reaction chamber, and decomposed to radicals. Alternatively, the Si-containing film forming composition may be introduced to the reaction chamber continuously while other metal sources are introduced by pulse (pulsed-chemical vapor deposition). In each example, a pulse may be followed by a purge or evacuation step to remove excess amounts of the component introduced. In each example, the pulse may last for a time period ranging from about 0.01 s to about 10 s, alternatively from about 0.3 s to about 3 s, alternatively from about 0.5 s to about 2 s. In another alternative, the Si-containing film forming composition and one or more co-reactants may be simultaneously sprayed from a shower head under which a susceptor holding several wafers is spun (spatial ALD).

In one non-limiting exemplary chemical vapor deposition type process, the vapor phase of a Si-containing film forming composition and a co-reactant, such as H₂, are simultaneously introduced into the reaction chamber, where they react to deposit the desired SiC film on the substrate.

In one non-limiting exemplary atomic layer deposition type process, the vapor phase of a Si-containing film forming composition is introduced into the reaction chamber, where it is contacted with a suitable substrate. Excess Si-containing film forming composition may then be removed from the reaction chamber by purging and/or evacuating the reaction chamber. An oxygen source is introduced into the reaction chamber where it reacts with the absorbed alkylamino-substituted carbosilane precursor in a self-limiting manner. Any excess oxygen source is removed from the reaction chamber by purging and/or evacuating the reaction chamber. If the desired film is a silicon oxide film, this two-step process may provide the desired film thickness or may be repeated until a film having the necessary thickness has been obtained.

Alternatively, if the desired film is a silicon metal/metalloid oxide film (i.e., SiMOₓ, wherein x may be 0-4 and M is Ta, Hf, Nb, Mg, Al, Sr, Y, Ba, Ca, As, Sb, Bi, Sn, Pb, Co, lanthanides (such as Er), or combinations thereof), the two-step process above may be followed by introduction of a second vapor of a metal- or metalloid-containing precursor into the reaction chamber. The metal- or metalloid-containing precursor will be selected based on the nature of the silicon metal/metalloid oxide film being deposited. After introduction into the reaction chamber, the metal- or metalloid-containing precursor is contacted with the substrate. Any excess metal- or metalloid-containing precursor is removed from the reaction chamber by purging and/or evacuating the reaction chamber. Once again, an oxygen source may be introduced into the reaction chamber to react with the metal- or metalloid-containing precursor. Excess oxygen source is removed from the reaction chamber by purging and/or evacuating the reaction chamber. If a desired film thickness has been achieved, the process may be terminated. However, if a thicker film is desired, the entire four-step process may be repeated. By alternating the provision of the Si-containing film forming compositions, metal- or metalloid-containing precursor, and oxygen source, a film of desired composition and thickness can be deposited.

Additionally, by varying the number of pulses, films having a desired stoichiometric M:Si ratio may be obtained. For example, a SiMO₂ film may be obtained by having one pulse of the Si-containing film forming composition and one pulses of the metal- or metalloid-containing precursor, with each pulse being followed by pulses of the oxygen source. However, one of ordinary skill in the art will recognize that the number of pulses required to obtain the desired film may not be identical to the stoichiometric ratio of the resulting film.

In another alternative, Si or dense SiCN films may be deposited via an ALD or modified ALD process using the disclosed Si-containing film forming compositions and a halosilane compound having the formula SiₐH_{2a+2-b}X_{b}, wherein X is F, CI, Br, or I; a=1 through 6; and b=1 through (2a+2); or a cyclic halosilane compound having the formula —Si_{c}H_{2c-d}X_{d}—, wherein X is F, CI, Br, or I; c=3-8; and d=1 through 2c. Preferably the halosilane compound is trichlorosilane, hexachlorodisilane (HCDS), pentachlorodisilane (PCDS), tetrachlorodisilane, or hexachlorocyclohexasilane. One of ordinary skill in the art will recognize that the CI in these compounds may be substituted by Br or I when lower deposition temperatures are necessary, due to the lower bond energy in the Si—X bond (i.e., Si—CI=456 kJ/mol; Si—Br=343 kJ/mol; Si—I=339 kJ/mol). If necessary, the deposition may further utilize an N-containing co-reactant, such as NH₃. Vapors of the disclosed compositions and the halosilane compounds may be introduced sequentially or simultaneously into the reactor, depending on the desired concentration of the final film. The selected sequence of precursor injection will be determined based upon the desired film composition targeted. The precursor introduction steps may be repeated until the deposited layer achieves a suitable thickness. One of ordinary skill in the art will recognize that the introductory pulses may be simultaneous when using a spatial ALD device. As described in PCT Pub No WO2011/123792, the order of the introduction of the precursors may be varied and the deposition may be performed with or without the NH₃ co-reactant in order to tune the amounts of carbon and nitrogen in the SiCN film.

In yet another alternative, a silicon-containing film may be deposited by the flowable PECVD method disclosed in U.S. Pat. App. Pub. No. 2014/0051264 using the disclosed Si-containing film forming compositions and a radical nitrogen- or oxygen-containing co-reactant. The radical nitrogen- or oxygen-containing co-reactant, such as NH₃ or H₂O respectively, is generated in a remote plasma system. The radical co-reactant and the vapor phase of the disclosed compositions are introduced into the reaction chamber where they react and deposit the initially flowable film on the substrate. Applicants believe that the carbon atom between the two Si atoms and the nitrogen atoms of the alkylamino groups in the disclosed alkylamino-substituted carbosilane precursors help to further improve the flowability of the deposited film, resulting in films having less voids.

The silicon-containing films resulting from the processes discussed above may include Si, SiO₂, SiN, SiON, SiC, SiCN, SiCOH, or MSiOₓ, whererin M is an element such as Hf, Zr, Ti, Nb, Ta, or Ge, and x may be 4, depending of course on the oxidation state of M. One of ordinary skill in the art will recognize that by judicious selection of the appropriate carbosilane precursor and co-reactants, the desired film composition may be obtained.

Upon obtaining a desired film thickness, the film may be subject to further processing, such as thermal annealing, furnace-annealing, rapid thermal annealing, UV or e-beam curing, and/or plasma gas exposure. Those skilled in the art recognize the systems and methods utilized to perform these additional processing steps. For example, the silicon-containing film may be exposed to a temperature ranging from approximately 200° C. and approximately 1000° C. for a time ranging from approximately 0.1 second to approximately 7200 seconds under an inert atmosphere, a H-containing atmosphere, a N-containing atmosphere, an O-containing atmosphere, or combinations thereof. Most preferably, the temperature is 600° C. for less than 3600 seconds under a H-containing atmosphere. The resulting film may contain fewer impurities and therefore may have improved performance characteristics. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the silicon-containing film.

### EXAMPLES

The following non-limiting examples are provided to further illustrate embodiments of the invention. However, the examples are not intended to be all inclusive and are not intended to limit the scope of the inventions described herein.

### Example 1

### Synthesis of [(EtHN)₃Si]₂CH₂ (Cl₃Si)₂CH₂+EtNH₂→[(NEtH)₃Si]₂CH₂

A two liter 3-neck flask is equipped with a −78° C. (dry ice/acetone) condensor, charged with pentane (200 mL) and cooled to −78° C. Liquid ethylamine was added to the flask (67.4 g, 1.49 mol). Bis(trichlorosilyl)methane (25 g, 0.088 mol) was slowly added via canuula over 1.5 hours. Formation of blue solids in a clear liquid was observed. After completing the addition, the suspension was slowly brought to room temperature with vigorous stirring. Sitrring continued overnight. The reaction mixture was filtered over a medium fritted glass filter. Solvents and high volatiles are removed under reduced pressure yielding a cloudy viscous liquid.

The resulting filtrate was then distilled using a short path column. The final product is distilled at 37-91° C./50-40 mTorr as a colorless liquid. Yield: 18 g (62%).

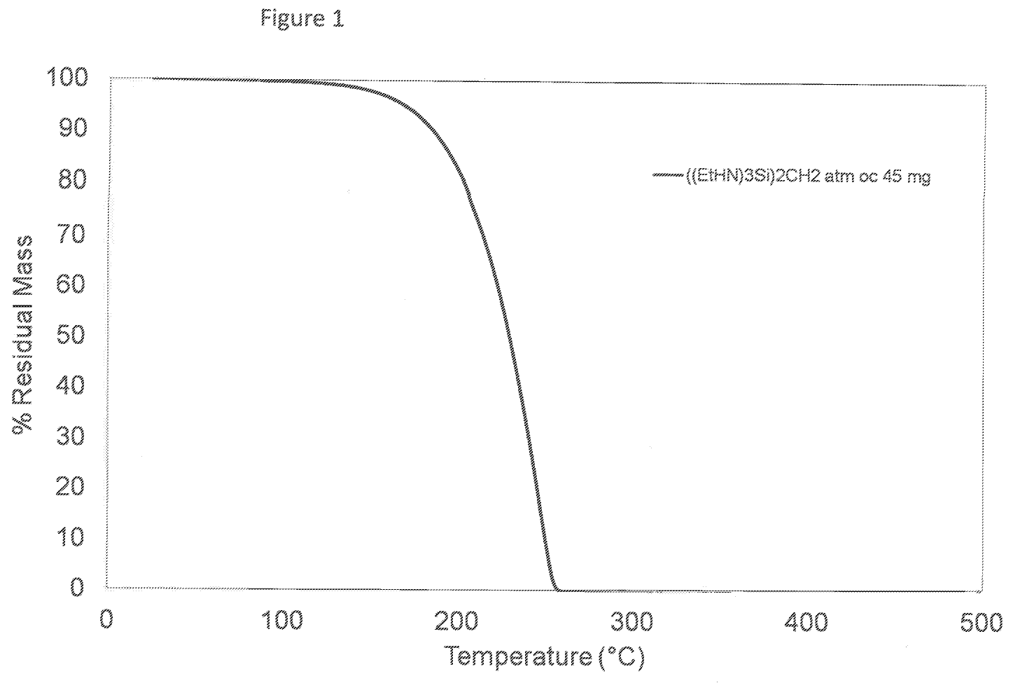

Thermogravimetric analysis (TGA) in open cup conditions produces less than 1% w/w residue. Closed cup TGA produces less than 4% w/w residue. See FIG. 1.

### Example 2

### Synthesis of (iPrHN)H₂Si—CH₂—SiH₃ H₃Si—CH₂—SiH₂Cl+iPrNH₂→(iPrHN)H₂Si—CH₂—SiH₃

A one liter 3-neck flask is equipped with a −78° C. (dry ice/acetone) condensor, charged with dry pentane (250 mL) and cooled to 0° C. Liquid isopropylamine was added to the flask (80.1 g, 1.355 mol). 1-chloro-1,3-disilapropane (54.5 g, 0.492 mol) was added slowly (1 drop per second) to the flask. Initially some fuming was observed followed by formation of a large amount of white solids in a clear liquid. An additional 150 mL of pentance was added and the mixture stirred for an additional 20 minutes. The suspension was slowly brought to room temperature with vigorous stirring. Sitrring continued overnight. The reaction mixture was filtered over a medium fritted glass filter to afford a clear colorless liquid. Solvents and high volatiles are removed using a short path column under atmospheric pressure at 32-37° C. The final product is distilled using a short path column under atmospheric pressure at 117-120° C. as a colorless liquid. Yield: 32 g (50%).

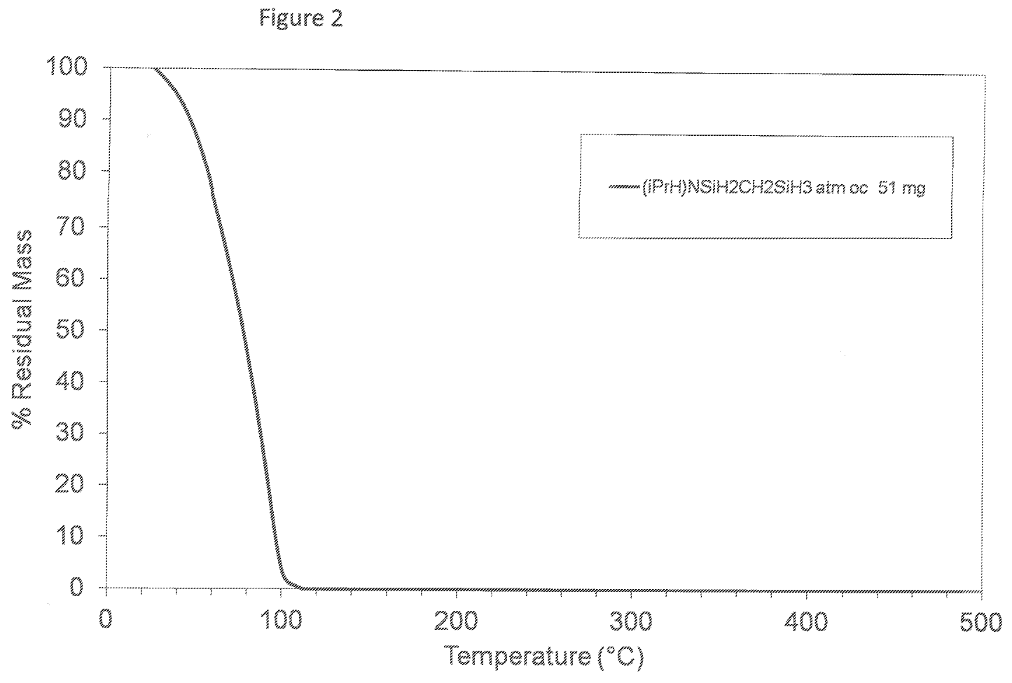

NMR of the final product NMR collected on a 400 MHz instrument. (iPrHN)SiH₂CH₂SiH₃in C₆D₆: ¹H NMR: δ—0.24 (m, 2H, —CH₂—), 0.15 (br, 1H, NH), 0.94 (d, 6H, —CH(CH₃)₂, 2.90 (m, 1H, —CH(CH₃)₂), 3.73 (t, 3H, J_{HH}=4.5 Hz, —SiH₃), 4.58 (m, 2H, —SiH2—); ²⁹Si NMR: δ—64.7, —65.3. Thermogravimetric analysis (TGA) in open cup conditions produces less than 1% w/w residue. See FIG. 2.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

What is claimed is:

1. A Si-containing film forming composition comprising a carbosilane precursor having the formula 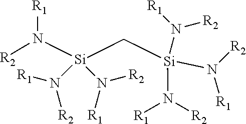
wherein R₁ is H and R₂ is each independently a C2-C6 alkyl group, a C1-C6 alkenyl group, or a C3-C10 aryl or heterocycle group, provided that R² is not Ph.

2. A process for the deposition of a Silicon-containing film on a substrate, comprising the steps of: introducing a vapor of the Si-containing film forming composition of claim 1 into a reactor having a substrate disposed therein and depositing at least part of the alkylamino-substituted carbosilane precursor onto the substrate to form the Silicon-containing film.

3. The process of claim 2, further comprising introducing at least one reactant into the reactor.

4. The process of claim 3, wherein the reactant is selected from the group consisting of H₂, H₂CO N₂H₄, NH₃, SiH₄, Si₂H₆, Si₃H₈, SiH₂Me₂, SiH₂Et₂, N(SiH₃)₃, hydrogen radicals thereof, and mixtures thereof.

5. The process of claim 3, wherein the reactant is selected from the group consisting of: O₂, O₃, H₂O, H₂O₂ NO, N₂O, NO₂, oxygen radicals thereof, and mixtures thereof.
